(19) United States
(12) Patent Application Publication
(10) Pub. No.: US 2024/0219286 A1
(43) Pub. Date: Jul. 4, 2024

(54) Particle Analysis Device and Particle Analysis Method

(71) Applicant: Hitachi High-Tech Corporation, Minato-ku, Tokyo (JP)

(72) Inventors: Erino MATSUMOTO, Tokyo (JP); Akiko HISADA, Tokyo (JP); Yuusuke OOMINAMI, Tokyo (JP); Ryo HIRANO, Tokyo (JP)

(21) Appl. No.: 18/558,469

(22) PCT Filed: Jun. 2, 2021
(86) PCT No.: PCT/JP2021/021042

§ 371 Date: Nov. 1, 2023

(51) Int. Cl. G01N 15/1433; G01N 15/14

(52) U.S. Cl. CPC G01N 15/1433; G01N 15/147; G01N 2015/1402

(57) ABSTRACT

A particle analysis device that analyzes one or more particles, the particle analysis device being capable of operating in any of a plurality of operation patterns, in which the plurality of operation patterns includes: a first operation pattern for determining, after an image of one or more particles prepared in a first time is acquired at a first magnification, whether a form of a single particle meets a first criterion; a second operation pattern for determining, after an image of a plurality of particles prepared in the first time is acquired, whether a brightness and an area of the plurality of particles meet a second criterion; and a third operation pattern for determining, after an image of a plurality of particles prepared in a second time longer than the first time is acquired at a second magnification lower than the first magnification, whether a number of the plurality of particles meets a third criterion.

### TECHNICAL FIELD

The present invention relates to a particle analysis device and a particle analysis method.

### BACKGROUND ART

Due to the development of nano micro-technology in recent years, industries using particles of about 100 nanometers to several hundred micrometers are increasing. For example, dielectric particles to be used in capacitors in association with miniaturization of electronic circuits, conductive fine particles to be used in electrode materials in association with increase in the capacities of batteries, and others are included. These particles are manufactured through a manufacturing process such as particle formation or crystal growth by crushing or sintering. While evaluation of these particles is important from the viewpoint of manufacturing, miniaturization of an acceptable size of foreign particles that may be mixed in a manufactured material is also in progress. That is, evaluation of particles as foreign substances that may be mixed in a material manufacturing process has also become important.

Microscope image analysis is used to inspect particles. In order to evaluate particles in more detail, an electron microscope having sufficient resolution is often used. PTL 1 discloses a method for speeding up collection of foreign substances contained in a liquid by controlling a filtration area. PTL 2 discloses a method for analyzing particles using an electron microscope.

### CITATION LIST

### Patent Literature

PTL 1: JP 2017-138226 A

PTL 2: JP 2012-238722 A

### SUMMARY OF INVENTION

### Technical Problem

However, in the conventional techniques (e.g., PTL 2), the observation conditions and inspection indexes of particles are single patterns, and the conventional techniques can only be applied to analysis of particles prepared under fixed conditions.

An object of the present invention is to provide a particle analysis device and a particle analysis method that can perform analysis according to conditions related to particles by operating in any of three operation patterns depending on the conditions related to particles.

### Solution to Problem

An example of a particle analysis device according to the present invention is a particle analysis device that analyzes one or more particles, the particle analysis device being capable of operating in any of a plurality of operation patterns, in which the plurality of operation patterns includes
a first operation pattern for determining, after an image of one or more particles prepared in a first time is acquired at a first magnification, whether a form of a single particle meets a first criterion,
a second operation pattern for determining, after an image of a plurality of particles prepared in the first time is acquired, whether a brightness and an area of the plurality of particles meet a second criterion, and
a third operation pattern for determining, after an image of a plurality of particles prepared in a second time longer than the first time is acquired at a second magnification lower than the first magnification, whether a number of the plurality of particles meets a third criterion.

An example of a particle analysis method according to the present invention is a particle analysis method for analyzing one or more particles, the particle analysis method being capable of being executed in any of a plurality of operation patterns, in which the plurality of operation patterns includes
a first operation pattern for determining, after an image of one or more particles prepared in a first time is acquired at a first magnification, whether a form of a single particle meets a first criterion,
a second operation pattern for determining, after an image of a plurality of particles prepared in the first time is acquired, whether a brightness and an area of the plurality of particles meet a second criterion, and
a third operation pattern for determining, after an image of a plurality of particles prepared in a second time longer than the first time is acquired at a second magnification lower than the first magnification, whether a number of the plurality of particles meets a third criterion.

### Advantageous Effects of Invention

According to the particle analysis device and the particle analysis method according to the present invention, it is possible to perform analysis according to conditions related to particles.

### BRIEF DESCRIPTION OF DRAWINGS

FIG. 1 is a simulated view of a form change in crystal growth.

FIG. 2 is a graph of an example showing a relationship between a particle size and the number with respect to changes in particles.

FIG. 3 is a flowchart according to a first embodiment of the present invention.

FIG. 4 is a table of an example showing a relationship between an observation magnification and a particle.

FIG. 5 shows views of examples of particle form images treated with a reagent.

FIG. 6 is a view illustrating examples of the states of particles according to intensities of luminance.

FIG. 7 is a flowchart of an example of collating a measurement result with a database.

FIG. 8 is a schematic view of an observation sample preparation device.

FIG. 9 is a schematic view of a filtration unit of the observation sample preparation device.

FIG. 10 shows schematic views of a membrane assembly.

FIG. 11 is a schematic view of frame shapes.

FIG. 12 is a schematic view of a filtration flow path of a single well.

FIG. 13 is a schematic view of well arrangement in a pipetting case.

FIG. 14 is a schematic view of a sample stage for observation.

FIG. 15 is a schematic view of a sample on a membrane.

FIG. 16 is an image showing an example of uniform recovery of particles using a pretreatment jig.

FIG. 17 is a configuration view of an example of a particle analysis device.

FIG. 18 is a view of an example of an operation screen.

FIG. 19 is a table showing a modification of a list of the respective conditions in a database.

### DESCRIPTION OF EMBODIMENTS

Hereinafter, the method for analyzing particles in embodiments of the present invention will be described in detail. Hereinafter, the term “particle” includes, but is not limited to, those described below.
A particle formed by crushing, sintering, or crystallization.
A three-dimensional structure, such as a step or a pattern, deposited or formed on a surface by corrosion, by plating, or by a chemical reaction of a battery or the like.
A vacancy or flaw occurring by degradation or etching of a material.
A foreign substance caused as an external factor.
A particle changed by applying an external stimulus (e.g., heating, vibration, pressurization, chemical change, or the like) to a certain particle.
An organic fiber, microplastic, pollen, cell, blood cell, bacteria, or virus.

Some examples in which the present invention is utilized are shown below. As a first example, a case, where determination is made by observing crystal growth, will be shown. In crystal growth using a seed crystal as a source of growth, crystal grows around the seed crystal and the shape of the particle changes after a short time in the initial stage of the growth. After a long time after the growth has progressed, the number of the particles decreases as adjacent crystals stick to each other. The present invention can be used in particle determination in such a case.

As a second example, a case, where determination is made by observing the growth of a flaw or vacancy in a material, is shown. In a situation where a reaction or tension that degrades a material is applied, a shape change in which the originally existing vacancy expands is shown in a short time, and in a long time the number of the vacancies themselves increases and the material degrades (such as a tensile test of a sheet). The present invention can also be used in such a case.

As a third example, a case, where determination is made by observing fine particle generation due to crushing of powder, is shown. In a fine particle manufacturing process in which powder is crushed, a shape change, such as removal of corners of particles forming the powder, occurs in a short time, but in a long time the particles themselves are crushed and changed into fine particles, whereby the total number of the fine particles increases. The present invention can be used in particle analysis in such a case.

By using the present invention in these cases, it is not necessary to make determination after a lapse of a long time by recognizing a shape change in a short time, whereby it is possible to obtain an effect of making inspection efficient.

### First Embodiment

Hereinafter, a first embodiment of the present invention will be described with reference to the drawings.

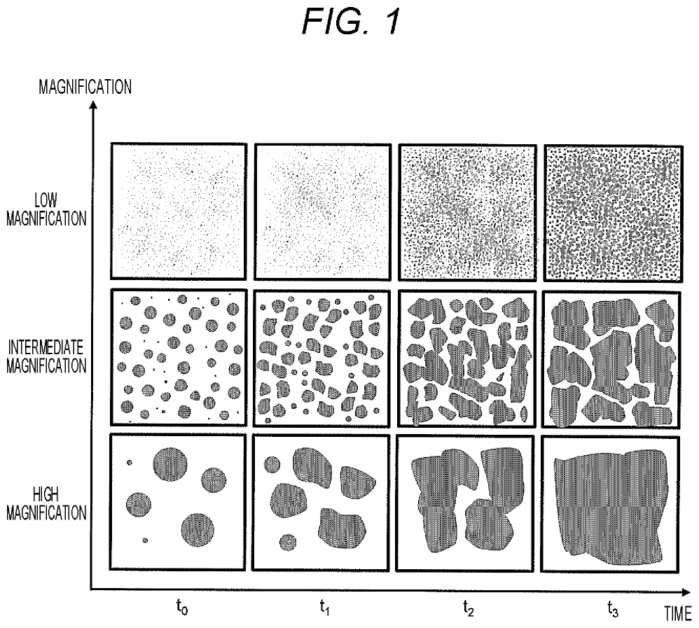

Details of changes in particles in crystal growth will be described with reference to FIG. 1. In the view, the horizontal axis represents time, and shows changes in particles over time. The vertical axis represents magnification in imaging. The images in the view are pattern diagrams of images acquired by the particle analysis device.

In the present embodiment, a change in the form of a single particle occurring from a time t0 to a time t1 is determined at a high magnification. The reason for the observation at a high magnification is that the form of a single particle can be observed in detail. On the other hand, when the number of particles is determined, the determination is made after a reaction is performed from t0 to t3, whereby the number of the particles can be determined. In addition, when an observation is made at an intermediate magnification, both the shape change and the number can be captured, and it is possible to determine how the particles behave as a particle group.

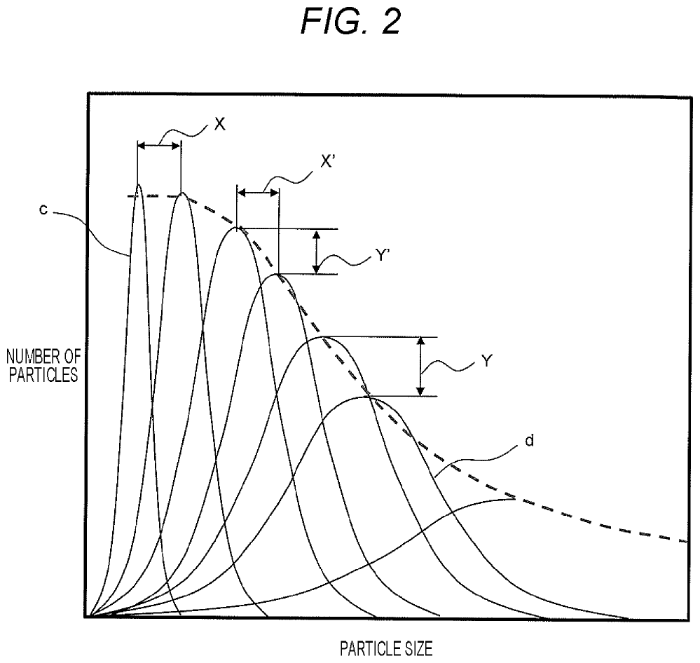

FIG. 2 shows how the distribution of particles changes with the horizontal axis representing particle size and the vertical axis representing the number of particles. Before the particles change, the number of the particles is large and the particle size is small, and thus the distribution is as shown by a graph c. After the particles change, the number of the particles is small and the particle size is large, and thus the distribution is as shown by a graph d. In the present embodiment, when the number of particles is evaluated, it is determined by a change amount Y along the vertical axis, and when an evaluation is made by particle size, it is determined by a change amount X along the horizontal axis. When the particle group is evaluated, it is determination by using a change amount Y′ in the number of particles along the vertical axis and a change amount X′ in a particle size along the horizontal axis. In determining the particle group, it may be determined by not only the size and number of particles but also a brightness thereof.

In FIGS. 1 and 2, a case, where the number of particles decreases with time, has been described, but the present embodiment can also be applied to a case where the number of particles increases with time.

When particles are manufactured, it may be necessary to inspect whether the particles are manufactured correctly. Alternatively, in order to confirm what process condition is good in manufacturing particles, particles generated under various reaction conditions may be evaluated.

In evaluating such particles, it is possible to select to observe at a high magnification by performing a reaction for a short time (the time t0 to the time t1 in FIG. 1) without performing a reaction for a long time (the time t0 to the time t3 in FIG. 1). In addition, in order to confirm whether particles can be manufactured correctly, it is possible to select to perform a reaction for a long time (the time t0 to the time t3 in FIG. 1), and in order to evaluate the number of particles, it is possible to select to observe at a low magnification.

That is, due to the present embodiment, an observation at a high magnification can be made when a form change in a particle that have reacted in a short time is captured, and an observation at a low magnification, in which a large number of particles, rather than the shapes thereof, can be counted, can be made when the particles are prepared over a long time, whereby particle determination can be made efficiently. In a particle manufacturing process, it is also possible to achieve manufacturing efficiency by, from an analysis result of an image obtained by an observation at a high magnification in a short time during the manufacture, detecting and reporting that there is a problem in the manufacturing conditions. With a database constructed, a result of analyzing the obtained image can also be used to optimize the manufacturing conditions and propose an improvement (solution proposal).

### Usefulness of Electron Microscope

In order to observe the number, type, forms, and the like of particles, it is preferable to have a resolution at which the forms of the particles can be analyzed in detail. Therefore, in order to make analysis of the number of particles, analysis of the type of the particles, and analysis of the forms of the particles, it is preferable to use an electron microscope in which an observation can also be made with a field of view of several tens of millimeters and the form of a structure with a nanometer size can be observed. Hereinafter, a method for analyzing particles using an electron microscope will be described in detail. However, the method and device described below can be applied to not only an electron microscope but also an optical microscope using light or laser, and the like.

### Particle Analysis Flow

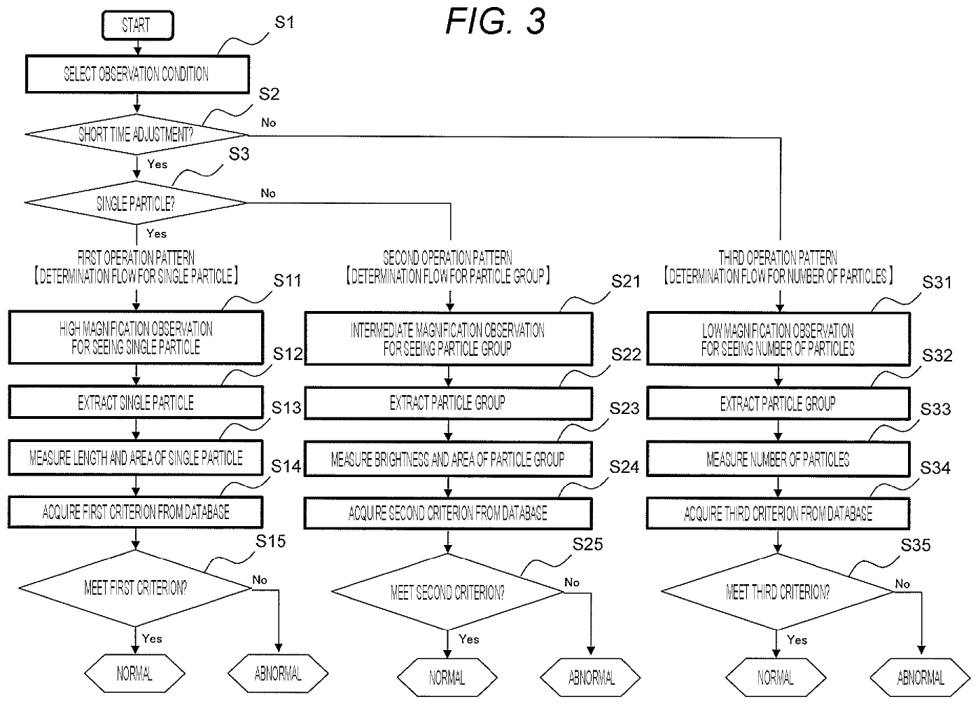

FIG. 3 is a flowchart for carrying out the present invention. The particle analysis device according to the present embodiment analyzes one or more particles by executing the method illustrated in FIG. 3.

First, the particle analysis device selects an observation condition for particles to be inspected (S1). For example, a user selects one of various observation conditions, and the particle analysis device receives an input thereof. The observation condition includes information indicating, for example, a material type of the particles, a preparation time, and an observation method (whether to observe a single particle or a plurality of particles).

The particle analysis device according to the present embodiment can operate in any of a plurality of operation patterns (including three operation patterns illustrated in FIG. 3). In addition, the particle analysis method according to the present embodiment can be executed in any of these operation patterns. The particle analysis device selects any one of the operation patterns according to the observation condition. The operation pattern is selected based on, for example, the preparation time (S2) and whether the analysis target is a single particle (S3).

In a case where the preparation time is short (e.g., equal to or less than a predetermined threshold) and a single particle is to be observed, a first operation pattern is selected. In the first operation pattern, an image of particles prepared in a first time (e.g., a relatively short time) is acquired at a first magnification (e.g., a relatively high magnification) (S11).

Next, the single particle is extracted (S12). A specific process for extracting an image of a single particle from an image including a plurality of particles can be appropriately designed by a person skilled in the art, and may be based on, for example, a known technique.

Next, the form of the extracted single particle is measured (S13). The form of the particle in the first operation pattern is represented by, for example, the area and length of the particle. Hereinafter, particle size displayed as a microscope image is described as a particle area, but the value actually measured from the image refers to information obtained by quantifying a diameter, a radius, a minor axis, a major axis, an area, a center of gravity, a shape, or the like that can be extracted from a two-dimensional microscope image. That is, the form, dimension, area, or the like of the particle may be a form, dimension, area, or the like in the microscope image, or may be represented by a value estimated or calculated on the basis of the microscope image. The definition of the “length” can be appropriately determined by a person skilled in the art, and the length can be, for example, a dimension in a direction in which the dimension of the particle becomes the largest. A specific process for acquiring the area and length of the particle on the basis of the image can be appropriately designed by a person skilled in the art, and may be based on, for example, a known technique.

Next, a first criterion on the form of a particles is acquired from the database (S14), and it is determined whether the form of the extracted single particle meets the first criterion (S15). For example, when each of the area and the length is within a predetermined range, it is determined that the first criterion is met, and when either or both are outside the predetermined range, it is determined that the first criterion is not met.

When the first criterion is met, the particle is determined to be normal, but otherwise the particle is determined to be abnormal. The result of the determination may be output to a display device or a storage device.

In a case where the preparation time is short and a particle group including a plurality of particles is to be observed, a second operation pattern is selected. In the second operation pattern, an image of particles prepared in the first time (e.g., a relatively short time) is acquired at predetermined intermediate magnification (e.g., a magnification lower than the first magnification and higher than a second magnification to be described later) (S21).

Next, a particle group including a plurality of particles is extracted (S22). A specific process for extracting an image of the particle group from an image including a plurality of particles can be appropriately designed by a person skilled in the art, and may be based on, for example, a known technique.

Next, the form of the extracted particle group is measured (S23). The form of the particles in the second operation pattern is represented by, for example, a brightness and an area of the particle group. The brightness can be represented by, for example, an intensity value of the luminance in the image. When the particle group is represented by a plurality of pixels, a statistical value (average value, standard deviation, histogram, or the like) of the brightness may be used. In addition, a specific process for acquiring the area of the particle group on the basis of the image can be appropriately designed by a person skilled in the art, and may be based on, for example, a known technique.

Next, a second criterion on the form of particles is acquired from the database (S24), and it is determined whether the form of the extracted particle group meets the second criterion (S25). For example, when each of the brightness and the area is within each predetermined range, it is determined that the second criterion is met, and when either or both are outside the predetermined range(s), it is determined that the second criterion is not met.

When the second criterion is met, the particle group is determined to be normal, but otherwise the particle group is determined to be abnormal. The result of the determination may be output to a display device or a storage device.

In a case where the preparation time is long (e.g., when exceeding a predetermined threshold), a third operation pattern is selected. In the present embodiment, the third pattern is an operation pattern for observing a particle group including a plurality of particles. In the third operation pattern, an image of particles prepared in a second time longer than the first time is acquired at a low magnification (i.e., a magnification lower than the first magnification and the intermediate magnification) (S31).

Next, a particle group including a plurality of particles is extracted (S32), and the number of the particles included in the particle group is measured (S33). A specific process for acquiring the number of the particles on the basis of the image of the particle group can be appropriately designed by a person skilled in the art, and may be based on, for example, a known technique.

Next, a third criterion on the number of particles is acquired from the database (S34), and it is determined whether the number of the extracted particles meets the third criterion (S35). For example, when the number of the particles is within a predetermined range, it is determined that the third criterion is met, and when the number of the particles is outside the predetermined range, it is determined that the third criterion is not met.

When the third criterion is met, the particle group is determined to be normal, but otherwise the particle group is determined to be abnormal. The result of the determination may be output to a display device or a storage device.

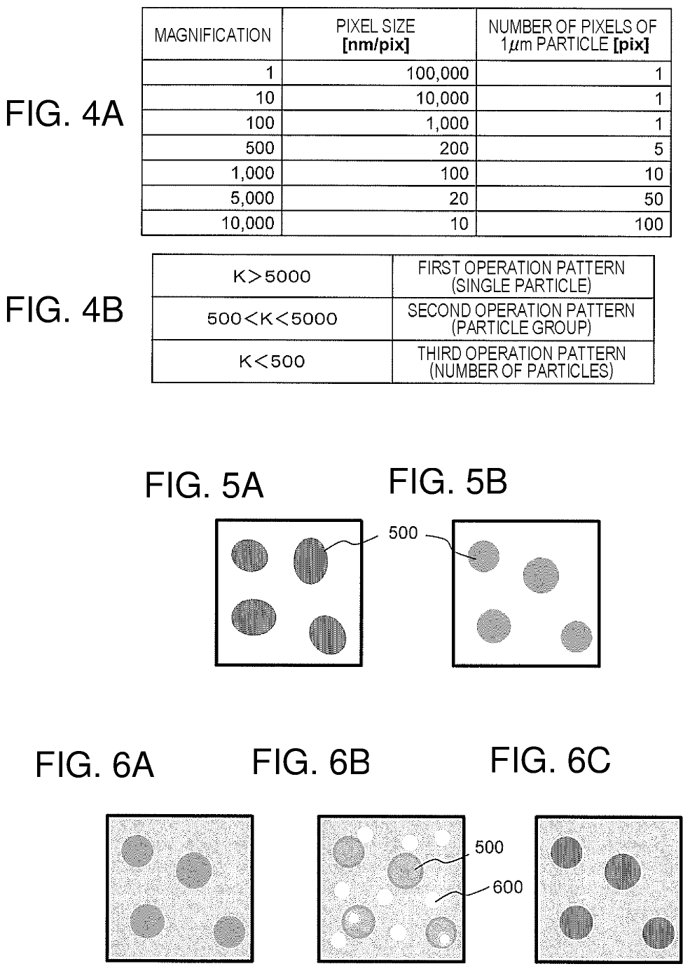

Hereinafter, setting of a magnification will be described in detail. In order to make a particle of 1 micrometer have a size of 1 pixel, the magnification is set to about 100 times from FIG. 4(a). Therefore, in the case of counting the number of particles of 1 micrometer, it is preferable to set the magnification to about 100 to 500 times so that one particle has a size of several pixels at minimum. In a case where the particle size is 10 micrometers, a suitable magnification is about 10 to 50 times.

On the other hand, in the case of grasping the details of the form of 1 micrometer particle, in order to set the image of the particle to about several tens of pixels, it is preferable to set the magnification to about 1000 to 5000 times or more from FIG. 4(a).

In addition, in a case where it is desired to evaluate as a group of particle of 1 micrometer or in a case where it is desired to evaluate the brightness of particles, in order to set the particle of 1 micrometer to about several pixels to several tens of pixels, it is preferable to set the magnification to about 500 to 5000 times.

Here, when it is assumed that the size of the particle is D [μm], the magnification is M [times], and a proportionality constant is K,

M=K/D

is satisfied. Considering from the practical number of image pixels, the proportionality constant K is as follows as illustrated in FIG. 4(b).

In a case where a single particle is evaluated in the first operation pattern: K>5000

In a case where a particle group is evaluated in the second operation pattern: 500<K<5000

In a case where the number of particles is evaluated in the third operation pattern: K<500

It is also possible to select an operation pattern on the basis of the proportionality constant K Instead of S2 and S3. For example, the particle analysis device acquires an observation magnification and a particle size in S1. Then, the particle analysis device can be configured such that when M=K/D is satisfied by assuming that the observation magnification is M [times], the particle size is D [μm], and the proportionality constant is K, the particle analysis device
operates in the first operation pattern when K>5000,
operates in the second operation pattern when 500<K<5000, and
operates in the third operation pattern when K<500. By setting three levels of magnification in this way, an appropriate image according to the state of particles is acquired.

An example of a method for further emphasizing a difference between the forms of particles is illustrated in FIG. 5. FIG. 5 shows schematic views of particles 500 treated with alcohol or a staining agent containing metal. FIG. 5(a) is an image of the particles treated with alcohol, and FIG. 5(b) is an image of the particles not treated with alcohol.

As shown in the image of FIG. 5(a), when particles are treated with alcohol, the alcohol penetrates into the particles and a part of the shape changes to a swollen form, and a grown particle, when compared to the form without alcohol treatment in FIG. 5(b), is observed. By treating the recovered particles with a reagent, such as a staining agent or alcohol, in this way, it is possible to more easily measure the characteristics of the particles. When the treated particles are used, it is possible to obtain an appropriate index for determining the situation and a state of the particles in a manufacturing process.

FIG. 6 is a view illustrating examples of the states of particles according to intensities of luminance. FIG. 6(a) is a view illustrating an example of a state in which the observed particle has a thickness and a staining solution does not penetrate into the particle. An image obtained only from reflected electrons from the surface of the particle is illustrated. FIG. 6(b) is a view illustrating an example of a state in which the observed particle has a less thickness, electron beams pass through the particle, and the state of the recovered instrument is also reflected. When there is a pattern 600 (pit or the like) having a different amount of reflected electrons in addition to the particles existing in the recovered instrument, an image reflecting the state is illustrated. FIG. 6(c) is a view illustrating a state in which a staining solution passes through the observed particle. An image, in which a straining solution penetrates into the inside of a particle depending on the state and property of the particle and the luminance of the particle image increases, is illustrated. For example, by the intensity of the luminance derived from a particle in an electron microscope image of the particle, the state of the particle can be known and an appropriate index for determining the situation at the time of preparation of the particle can be obtained, as described above.

Instead of or in addition to the form of the particle, based on the intensity of the luminance in a microscope image and the level of staining (which can be acquired based on, for example, the intensity distribution of the luminance), a user can grasp the thickness and composition of a particle, as described above, and can also use them as a determination criterion.

In addition, when a pattern, having a different amount of reflected electrons from a particle, exists on an observation surface on which the particle is recovered and the pattern is reflected onto the observation image of the particle according to the electron beam transmission level of the particle, a user can also use this pattern as a criterion for determining whether the particle is normal, instead of or in addition to the form of the particle.

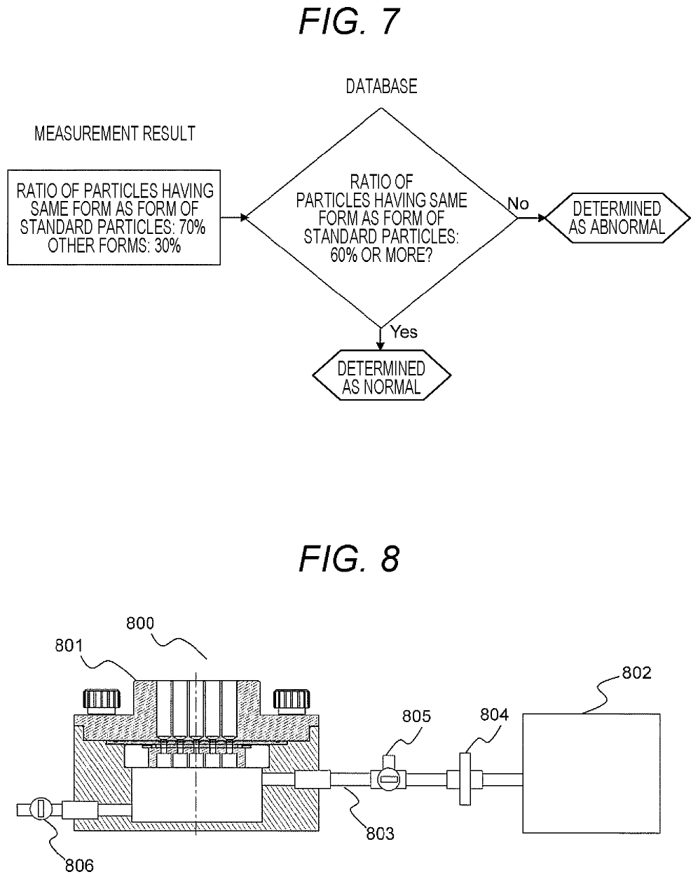

FIG. 7 is a flowchart of an example of collating the measurement result of a particle with the determination criterion in the database. For example, when a particle prepared by particle crystal growth is inspected, the determination in the first operation pattern can be repeated multiple times to make further comprehensive determination.

For example, the forms of a plurality of particles are extracted from an observation image, and each particle is determined in the first operation pattern. As an example of the determination result, it is assumed that particles, each having a form corresponding to a standard particle (i.e., a form determined to be normal in S15 of FIG. 3), are contained in 70% and particles, each having another form (i.e., a form determined to be abnormal in S15 of FIG. 3), are contained in 30%. In addition, it is assumed that the database stores a criterion that the forms corresponding to the standard particle exist in 60% or more.

In this case, the ratio of the particles, each having a form corresponding to the standard particle, meets the criterion, and thus the prepared particles are determined to be normal in the process of FIG. 7. This threshold can be determined in advance according to a combination of a material and a preparation state or a condition.

Note that, in the above example, the determination in the first operation pattern is repeated, but as a modification, the process of FIG. 7 may be performed by one time of the process in the second operation pattern. For example, the particle analysis device may determine whether each particle included in a particle group corresponds to the standard particle, and determine whether the particle group is normal based on the ratio of the particles corresponding to the standard particle. In this case, the second criterion may include a criterion on the ratio of particles corresponding to the standard particle instead of or in addition to the criterion on the form of the particle.

### Description of Particle Collection Unit

In order to analyze particles, the particles adhering onto a material may be observed, but in a case where the number of the particles is small or in a case where the size of a material itself to be observed is large, it is very troublesome to evaluate the number and shapes of the particles. Therefore, the particles are transferred into liquid or gas, the particles are aspirated onto a filter, and the filter is observed, whereby the particles can be analyzed. Hereinafter, a detailed example of a method will be described, the method regarding filtering particles existing in a liquid using a filter and observing the particles on the filter.

The particle analysis device may include an observation sample preparation device that prepares an observation sample by concentrating particles. FIG. 8 illustrates an example of a configuration of an observation sample preparation device 800. The observation sample preparation device 800 includes
a filtration unit 801 for filtering a liquid containing particles,
a vacuum exhaust pump 802 that generates a pressure difference to be used for liquid filtration,
a pipe 803 for connecting the vacuum exhaust pump 802 and the filtration unit 801,
a filter 804 for preventing the inflow of fine particles from the filtration unit 801 to the vacuum exhaust pump 802,
an exhaust valve 805 for switching between a vacuum exhaust state and an atmosphere open state, and
a drain valve 806 for discharging drainage having occurred through the filtration.

The filtration unit 801 passes a liquid containing particles through a membrane having a large number of micropores, whereby a sample, in which particles are dispersed on the membrane, can be prepared. As the vacuum exhaust pump 802, a pump capable of operating at low vacuum, like, for example, a diaphragm vacuum pump or a dry pump, is used. As the pipe 803, a pipe made of, for example, metal or rubber is used. The filter 804 is used for the purpose of preventing aspiration of fine particles into the vacuum exhaust pump 802 and preventing failure of the vacuum exhaust pump 802 and release of fine particles from the exhaust port of the vacuum exhaust pump 802. As the filter 804, an air filter like, for example, a HEPA filter is used. As the exhaust valve 805, an exhaust valve of a manual type or an electric type can be used. When that of an electric type is used, operation can be simplified by being linked with the operation of the vacuum exhaust pump 802. As the drain valve 806, a drain valve of a manual type or an electric type can be used, but it is preferable to use a valve resistant to a liquid to be used.

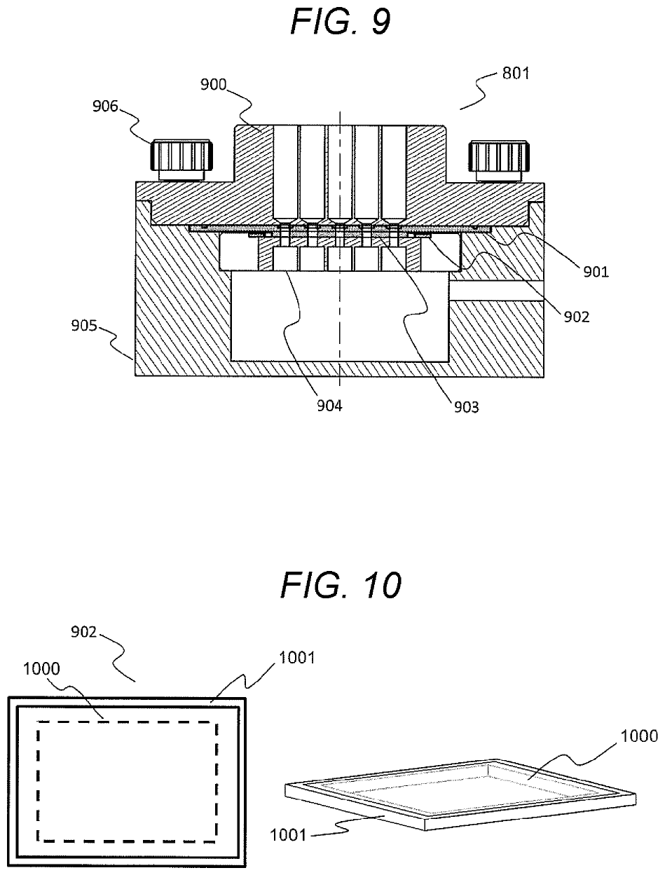

FIG. 9 illustrates an example of the filtration unit 801 in the observation sample preparation device 800. The filtration unit 801 includes
a pipetting case 900 for pipetting and holding a liquid containing particles,
a membrane assembly 902 consisting of a membrane for filtering the particles contained in the liquid and a frame for supporting the membrane,
an upper sealing material 901 for preventing liquid leakage between the pipetting case 900 and the membrane and for maintaining a pressure difference between the inside and outside of the filtration unit 801,
a support plate 904 for mounting the membrane assembly,
a lower sealing material 903 for preventing liquid leakage between the membrane and the support plate,
a base 905 for storing drainage having occurred through the filtration by the membrane, and
a fixing screw 906 for fixing the pipetting case 900 to the base and for bringing the membrane into close contact with the sealing materials.

The pipetting case 900 has a plurality of wells for pipetting a liquid containing particles, and can simultaneously filter a plurality of different liquids. The capacity of each well of the pipetting case 900 depends on the concentration of a liquid to be filtered and the conditions of staining and washing treatment. The capacity is about 100 to 2000 ml. The flow path diameter at the lower portion of each well of the pipetting case 900 affects the number of particles existing in one field of view at the time of an observation using a microscope. For example, when 1 ml of a liquid having a concentration of 150,000 particles/ml is filtered using the pipetting case 900 having a flow path diameter φ2 mm at the lower portion of the well and microscopic observation is performed in an observation field of view of 0.0002 mm², 10 fine particles can be observed per field of view. By concentrating and recovering particles at a density at which one or more particles can be observed in an area of 0.0001 to 0.01 mm² per field of view of an observation image when observed with a microscope at a magnification of 100 times to 10,000 times, particles can be observed by observing any field of view, and thus the time for the observation can be shortened.

For example, when the diameter of the filtration flow path of the observation sample preparation device 800 for recovering particles is set to 6 mm, and when 1 mL of a particle suspension of 10⁵ particles/mL is recovered and an observation is made at a magnification of 10,000 times, it is possible to observe one particle per observation image. For example, when the size of a particle is 1 μm², and when the area of 10⁵ particles occupies a half of the recovery surface, the diameter of the filtration flow path of the observation sample preparation device 800 for recovering particles is desirably 0.5 mm.

If the diameter of the observation sample preparation device 800 is too small, it takes time t0 perform aspiration filtration. When the diameter of the observation sample preparation device 800 is large and bubbles occur on a part of the bottom surface, bacteria are not recovered there, and thus uniformity cannot be maintained. In addition, when the diameter of the observation sample preparation device 800 is small and bubbles cover the entire bottom surface, aspiration filtration cannot be performed, and particles may not be recovered. Depending on conditions such as the concentration in the liquid and the amount of the liquid, the size of the flow path diameter of the filtration flow path is desirably about φ0.5 to 6 mm.

By making the flow path diameter at the lower portion of the well equal to or smaller than the diameter at the upper portion of the well, a sample, in which particles are dispersed in a high density, can be prepared even when the amount of a liquid to be pipetted is small.

In addition, the lower surface of the pipetting case 900 is provided with a convex structure for enhancing adhesion with the upper sealing material and preventing leakage. A chemical resistant material is used for the upper sealing material 901 and the lower sealing material 903, and a similar pit structure is provided at the same position as the flow path of the pipetting case 900. At this time, in order to make the area for recovering particles constant, it is preferable that the diameter of the pit structure of the lower sealing material 903 has a diameter corresponding to the area for the recovery and the upper sealing material 901 has a diameter larger than the diameter of the lower sealing material. In this case, the pit of the lower sealing material 903 is located in the pit of the upper sealing material 901, and thus particles are always recovered in the area of the lower sealing material, whereby it is possible to suppress a variation in the recovery area due to a slight positional displacement of the materials.

The membrane assembly 902 fixes a membrane, which is thin and difficult to handle as a single body, to the frame, whereby it has a role of facilitating attachment/detachment to/from the filtration unit 801 and mounting on the sample stage of a microscope.

The support plate 904 has a pit structure as a flow path at the same position as the pipetting case 900, the upper sealing material 901, and the lower sealing material 903. The support plate 904 has a thickness such that, when the fixing screw is tightened and the sealing material is pressed, the support plate 904 is not curved, and has a counterbore pit from the lower surface side of each flow path in order to reduce the aspect ratio between the flow path diameter and the flow path length and reduce the pressure loss of the flow path. In addition, the support plate 904 has a groove structure for fitting the frame to align the position of the membrane assembly.

The base 905 has a capacity for storing drainage having occurred through one time of the filtration treatment. In addition, the base 905 has a port for exhaust and a port for drainage. The port for exhaust is positioned above the port for drainage in order to prevent the inflow of liquid. The pipetting case 900, the support plate 904, and the base 905 are made of a material resistant to a liquid to be used. In addition, when the pipetting case 900 and the base 905 is made of a transparent material, the state of the filtration treatment can be visually recognized from the outside of the unit.

FIG. 10 illustrates an example of a membrane assembly to be used in the filtration unit 801. The membrane assembly 902 is constituted by a membrane 1000 and a frame 1001. The membrane 1000 is a polymer material sheet having a large number of fine pores of about 10 nm to 10 μm, and has a thickness of several μm to several tens of μm. The membrane 1000 is fixed to the frame 1001 with a tape or an adhesive. When made of a conductive material, the frame 1001 can alleviate electrification due to an electron beam, for example, when electron microscopic observation is made. In addition, it is also effective for alleviating electrification by an electron beam to perform a conduction treatment, such as coating with gold or platinum, directly on the membrane 1000.

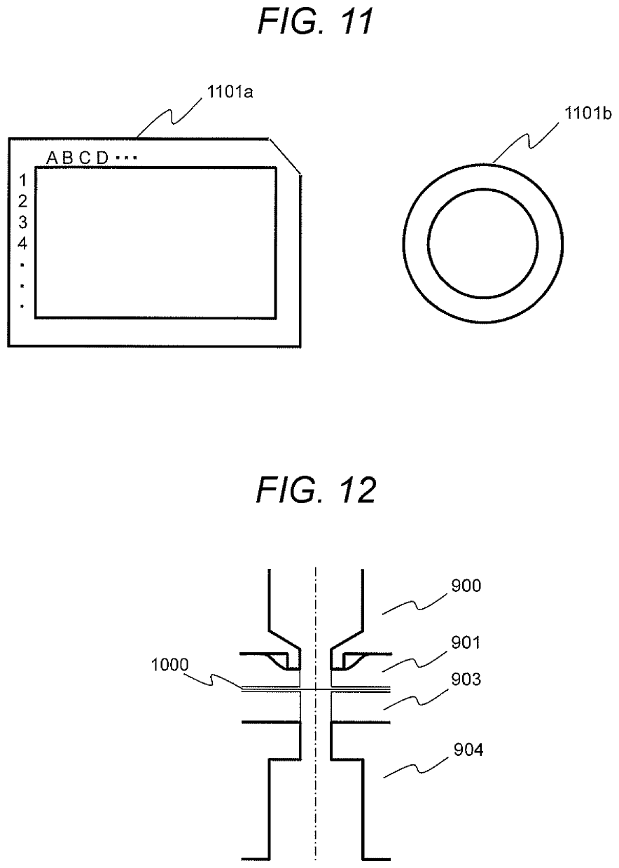

FIG. 11 illustrates frames of the membrane assembly. As the frame, a quadrangular frame 1101a or a round frame 1101b is used. The frame has a cut-out shape or an engraved mark indicating the direction of the frame when it is mounted on the sample stage of a microscope. In addition, if an alphanumeric character or a symbol is written on the frame, it is possible to number and manage samples for each well.

FIG. 12 illustrates an example of a cross-section of the filtration flow path of a single well in the filtration unit. When the flow path diameter at the lower portion of the pipetting case 900 is smaller than the well diameter at the upper portion, it is possible to reduce the residual of a pipetting liquid in the well by forming a tapered shape between the upper well and the lower flow path. In addition, the cross-sectional shapes of the well and the filtration flow path may be polygonal instead of circular. However, if the cross-section of the filtration flow path is polygonal, the flow rate at the corner decreases due to the resistance of the flow path wall surface, which impairs uniformity of filtration. Therefore, the cross-sectional shape of the flow path is preferably circular rather than polygonal. The counterbore pit from the lower surface of the support plate 904 may have a counterbore shape as illustrated in the view or another tapered shape.

FIG. 13 illustrates an example of well arrangement in a pipetting case 1301 in the filtration unit. The pipetting case 900 includes a plurality of wells 1300, and the respective wells are arranged at equal intervals in each of the row direction and the column direction. Therefore, it is possible to simultaneously pipette a liquid into the plurality of wells using a pipetting device having a plurality of pipettes. In particular, when the interval between the wells is matched to a commercially available multi-pipette, it can be used in a more versatile process. However, the interval between the wells may be determined to match an arbitrarily designed pipette.

The number of the wells is determined by the movable range of the stage of a microscope and the interval between the filtration flow paths. For example, when, in the stage having a movable range of 50 mm in the X direction, the interval between the filtration flow paths is set to 9 mm and the flow path diameter to φ3 mm, five wells can be provided in the X direction. The interval between the flow paths is not necessarily equal to the interval between the wells. When it is desirable to create more observation regions in the movable range of the stage, it is better to make the interval between the flow paths narrower than the interval between the wells.

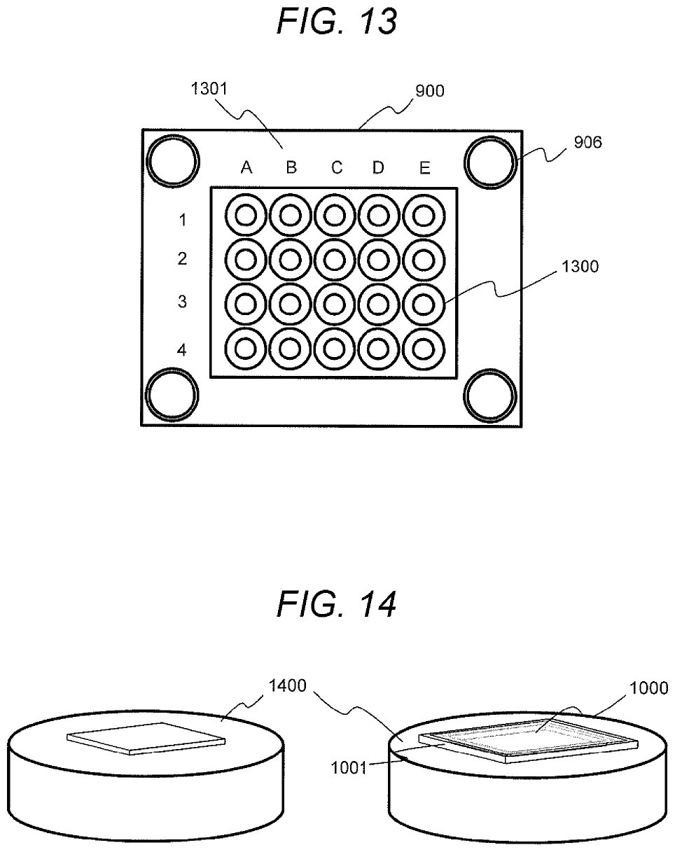

FIG. 14 illustrates an example of the sample stage for microscopic observation. A sample stage 1400 is used to mount the membrane assembly on the stage of a microscope. When an observation is made using, for example, an electron microscope, a nonmagnetic metal, such as aluminum or copper, is used, and when the sample stage 1400 is brought into close contact with the membrane, electrification due to an electron beam can be alleviated. The sample stage 1400 has a shape matching the frame 1001 of the membrane assembly, and can mount the sample on the microscope stage with high accuracy, which is advantageous in automatic sample mounting and imaging.

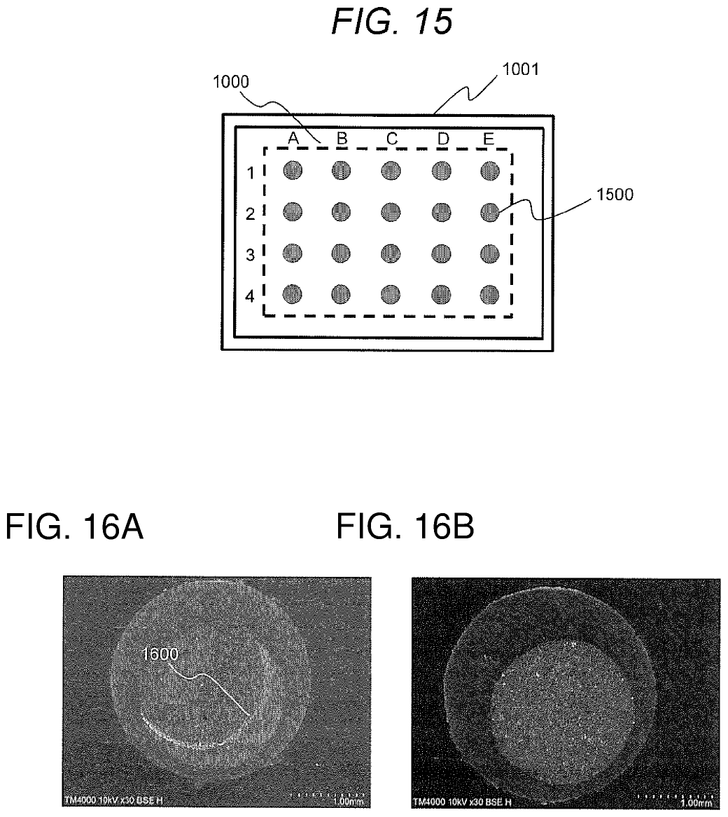

FIG. 15 illustrates an example of samples sampled on the membrane. Since the samples are colorless and transparent depending on a liquid to be filtered, it is difficult to visually confirm the positions of the samples. In such a case, by storing in advance the position coordinates of a filtration part 1500 on the membrane in association with the stage coordinates of a microscope, the positions of the samples can be easily identified and observed.

FIG. 16 shows an example in which the luminance value of all particles can be calculated from an image obtained by observing a part of the recovery surface by uniformly recovering the particles using the sample stage 1400 for microscopic observation. FIG. 16 is an image showing an example of uniform recovery of particles using the for sample stage 1400 microscopic observation.

FIG. 16(a) is an example of a state in which the recovered particles are not uniformly dispersed. A white mass is seen on a line in a part of the recovered circle, which shows that there is particle aggregation 1600. In this case, the density of the particles varies depending on a position to be observed, and thus it is preferable to observe the entire recovery surface in order to measure and compare the number of the particles.

In addition, even in the case of making an observation at a high magnification, it is difficult, upon extracting the form of a single particle, to extract the forms of individual particles if the particles are recovered in an aggregated state, and there is also a possibility that the forms may change due to the aggregation.

When a liquid is fed only to a part of the recovery surface and the liquid is aspirated before the liquid spreads over the entire recovery surface, particles may be recovered only in the part. Since there is the pipetting case 900 for pipetting and holding a liquid on the sample stage 1400, the liquid to be recovered can be held and filtered through the entire recovery surface, whereby the particles can be recovered in a state of being uniformly dispersed on the recovery surface.

FIG. 16(b) is an example of a state in which the recovered particles are uniformly dispersed. Since there is no variation in the density of particles regardless of observation positions, it is possible to convert into the luminance value, the number of particles, and the like of the entire particles by observing a part of the particles. For example, by uniformly dispersing particles on a plane and recovering them, measurement can be performed by observing with an electron microscope a part of the recovery surface, rather than the entire of the recovery surface, and determination on the particle can be made more appropriately. In addition, the individual particles do not aggregate and do not overlap, so that it is easy to extract the form of each particle. For the species of a particle that constitutes a three-dimensional aggregate in the process of increasing the number of the particles, it is possible to observe and measure the particles in the height direction by tilting the sample stage of a microscope.

In the particle analysis device, it is preferable to disperse particles over an image acquisition range by pipetting a liquid into the particles and filtering the liquid over the entire image acquisition range, as described above.

According to the particle analysis device and the particle analysis method according to the first embodiment, it is possible to perform analysis according to the conditions related to particles, as described above.

### Second Embodiment

In a second embodiment, further components are added to the particle analysis device of the first embodiment. Hereinafter, description of parts common to the first embodiment may be omitted.

### Device Configuration

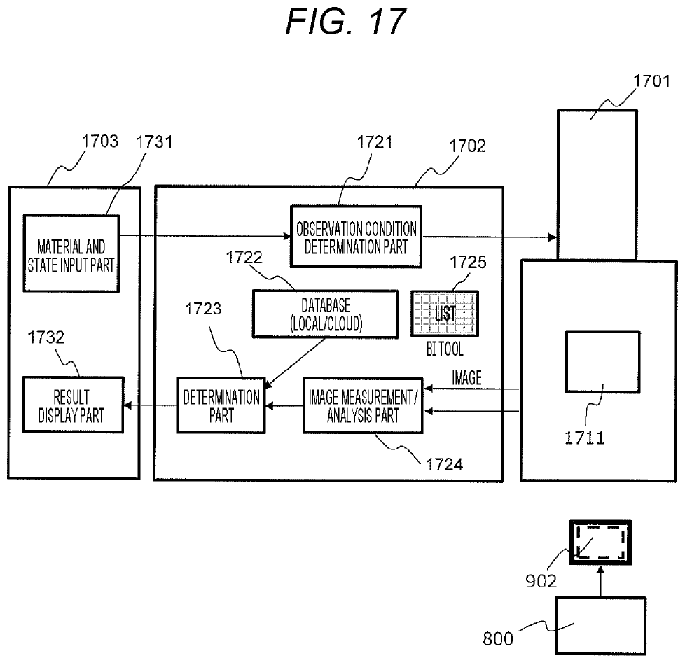

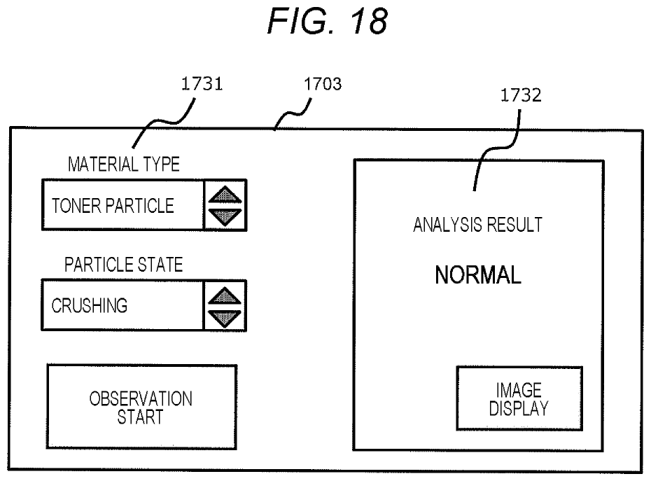

FIG. 17 is a configuration view of an example of a particle analysis device. The particle analysis device includes
the observation sample preparation device 800 that prepares a sample by concentrating particles on a plane at a density appropriate for observation,
a microscope 1701 (e.g., an electron microscope) that observes recovered particles and acquires an image of the particles,
a control/analysis device 1702 that determines an observation condition for the particles, analyzes the image of the observed particles, and displays a result, and
a display that displays an operation screen 1703 (which will be described in detail with reference to FIG. 18) including a material and state input part 1731 (particle parameter input part) for inputting a type of a particle (e.g., a material type and a manufacturing condition), a state, and the like, and a result display part 1732 for displaying a result of determination. With such a configuration, it is possible to consistently perform from the input of conditions to the output of a result by the particle analysis device alone. In particular, input of particle parameters and result display can be performed on one screen.

The microscope 1701 includes an arrangement part 1711 that is attached to observe the membrane assembly 902 on which the particles are recovered by the observation sample preparation device 800.

The control/analysis device 1702 includes
an observation condition determination part 1721 that determines an observation condition in the microscope on the basis of information on the input material type and particle state,
an image measurement/analysis part 1724 that acquires an observation image by the microscope and measures and analyzes the particles in the image,
a database 1722 that stores the analysis results of particles so far and determination thresholds, and
a determination part 1723 that determines an analysis result of the particles by collating the information obtained by the image measurement/analysis part with a determination threshold in the database.

The database 1722 may store information indicating the first criterion, the second criterion, and the third criterion. In addition, the database 1722 may store programs for making determinations related to the first criterion, the second criterion, and the third criterion. Further, the database 1722 may store various lists 1725 to be used in a business intelligence (BI) tool. With such a database 1722, various criteria and algorithms can be prepared in advance to be used.

The database 1722 in the control/analysis device 1702 may be a cloud server or the like to be connected to the Internet. That is, the particle analysis device may be connected to an external computer via a communication network, and the particle analysis device may acquire information indicating the first criterion, the second criterion, or the third criterion from the external computer. In addition, the particle analysis device may acquire a program for making a determination related to the first criterion, the second criterion, or the third criterion from the external computer. With such a configuration, various criteria and algorithms can be appropriately acquired and used.

The observation condition determination part 1721 determines the operation pattern of the microscope 1701 on the basis of information on the particle preparation time, the preparation conditions, or the like input to the material and state input part 1731. More specifically, the operation pattern may be determined based on conditions determined in advance, such as an acceleration voltage and a magnification, and along the flow described with reference to FIG. 3. That is, it is determined depending on the time required to prepare particles whether the particles are to be observed at a high magnification or a low magnification, or the like.

Next, an image, acquired under an observation condition based on the determined operation pattern, is input to the image measurement/analysis part 1724. In addition, the determination threshold is acquired with reference to the database 1722 on the basis of the information on the particle preparation time, the preparation condition, and the like input to the material and state input part 1731.

The image measurement/analysis part 1724 calculates numerical data, such as luminance distribution, contrast, size, length, or area, from the acquired image or particle information. The calculated numerical data is input to the determination part 1723 and compared to the determination threshold output from the database 1722. The comparison result is displayed in the result display part 1732 on the operation screen 1703.

The image measurement/analysis part 1724 extracts a feature amount (form or number) of each particle in the image and analyzes a difference from the feature amount of the standard particle (which is used in determination with, for example, the first criterion, the second criterion, and the third criterion). For example, when the mechanical properties of the manufactured particle are to be evaluated, a user may evaluate the manufactured particle: by preparing a particle obtained by applying an external stimulus, such as stress or strain, to the manufactured particle and a particle before being applied therewith; by observing both; and from an analysis result in which the feature amounts of the particles in the images are compared.

As the feature amount of the standard particle, it is also possible to use an image observed in the past and accumulated in the image measurement/analysis part 1724 or information extracted from the image.

FIG. 18 is a view illustrating an example of the operation screen 1703 including the material and state input part 1731 and the result display part 1732. A user selects, from tabs registered in advance, the material type, particle state, and the like of particles to be analyzed in the material and state input part 1731, and then presses the observation start button, whereby the process of FIG. 3 is started.

The material type and the particle state can be newly added, and in this case, the data of the database 1722 are also updated. In the result display part 1732, an image analysis result (e.g., “normal” or “abnormal”) of a particle is displayed. It is also possible to display, by pressing the image display button, the analyzed image on the display to be confirmed.

For example, when toner particles manufactured through a crushing process are analyzed, and when a toner particle is selected as the material type and crushing is selected as the particle state and the observation start button is pressed, microscopic observation is automatically started, and an analysis result is displayed in the result display part after the image analysis. As the analysis result, an analysis score or the like can also be displayed in addition to normal or abnormal.

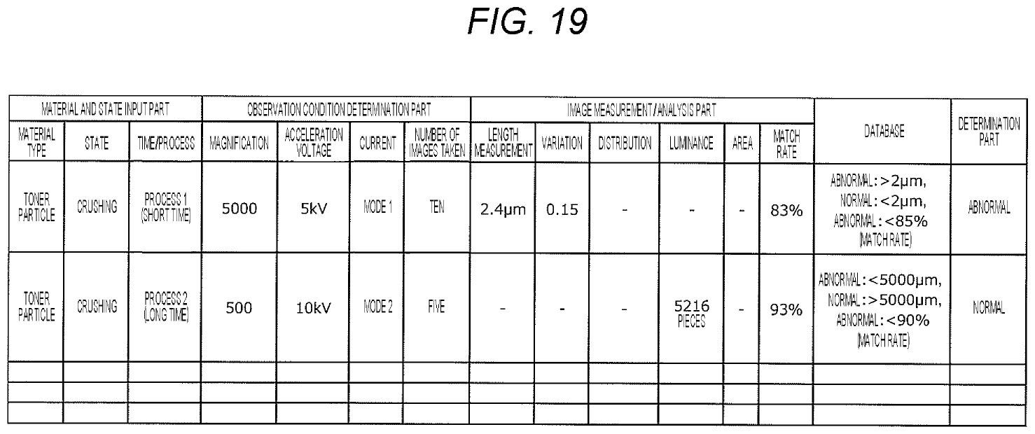

FIG. 19 is a table showing a modification of a list of the respective conditions in the database. Microscopic observation is performed under the observation conditions listed in the list of FIG. 19 on the basis of the information on the material type and state input to the material and state input part 1731. The observation image is measured using a determined index and collated with the threshold described in the database 1722, whereby normal/abnormal is determined.

For example, when toner particles manufactured by crushing are to be analyzed using an electron microscope, toner particles, crushing conditions, and the like are input to the material and state input part 1731 and a manufacturing process (e.g., a short-time inspection or a long-time inspection, not illustrated in FIG. 18), when analysis is performed, is input, whereby conditions, such as a magnification and an acceleration voltage, set in advance in the observation condition determination part 1721 are read. For the image observed under the designated conditions, the particles are measured by the index designated by the image measurement/analysis part 1724.

When toner particles manufactured by crushing are inspected using a short-time inspection (process 1) illustrated in FIG. 19, it is designated to acquire 10 images at a magnification of 5000 and an acceleration voltage of 5 kV, and in a current pattern 1. For the acquired images, the form of the particle is then measured and compared to the form of the standard particle. A match rate (e.g., the proportion of particles determined to be normal among all the determined particles) of the inspected particles to the standard particle is also analyzed. The match rate may be further evaluated based on the criteria stored in the database 1722 to be compared to a threshold, and a comprehensive result may be displayed in the result display part 1732. When a material type and a state are input to the material and state input part 1731, an index to be measured by the image measurement/analysis part 1724 is designated.

### Third Embodiment

In the first and second embodiments, particles are concentrated and stained using the observation sample preparation device 800 illustrated in FIG. 8, and then the recovery surface is observed for its appearance or observed with a microscope to measure luminance, whereby the density of the particles recovered on the surface and the concentration of the filtered particles can be calculated.

### REFERENCE SIGNS LIST

500 particle
600 pattern
800 observation sample preparation device
801 filtration unit
802 vacuum exhaust pump
803 pipe
804 filter
805 exhaust valve
806 drain valve
900 pipetting case
901 upper sealing material
902 membrane assembly
903 lower sealing material
904 support plate
905 base
906 fixing screw
1000 membrane
1001 frame
1101a quadrangular frame
1101b round frame
1300 well
1301 pipetting case
1400 sample stage
1500 filtration part
1600 particle aggregation
1701 microscope (electron microscope)
1702 control/analysis device
1703 operation screen
1711 arrangement part
1721 observation condition determination part
1722 database
1723 determination part
1724 image measurement/analysis part
1725 list
1731 material and state input part (particle parameter input part)
1732 result display part

1. A particle analysis device that analyzes one or more particles, the particle analysis device being capable of operating in any of a plurality of operation patterns, wherein the plurality of operation patterns include
a first operation pattern for determining, after an image of one or more particles prepared in a first time is acquired at a first magnification, whether a form of a single particle meets a first criterion,
a second operation pattern for determining, after an image of a plurality of particles prepared in the first time is acquired, whether a brightness and an area of the plurality of particles meet a second criterion, and
a third operation pattern for determining, after an image of a plurality of particles prepared in a second time longer than the first time is acquired at a second magnification lower than the first magnification, whether a number of the plurality of particles meets a third criterion.

2. The particle analysis device according to claim 1, comprising an electron microscope that acquires the image.

3. The particle analysis device according to claim 2, comprising:
an observation sample preparation device that prepares a sample by concentrating the one or more particles;
a database that stores information indicating the first criterion, the second criterion, and the third criterion; and
a display that displays a result of the determination.

4. The particle analysis device according to claim 1, wherein:
the particle analysis device acquires an observation magnification and a particle size; and
when it is assumed that the observation magnification is M times, the particle size is D micrometers, a proportionality constant is K, and M=K/D, the particle analysis device
operates in the first operation pattern when K>5000,
operates in the second operation pattern when 500<K<5000, and
operates in the third operation pattern when K<500.

5. The particle analysis device according to claim 1, wherein the one or more particles are particles treated using alcohol or a staining agent containing metal.

6. The particle analysis device according to claim 1, the particle analysis device dispersing the one or more particles over an image acquisition range by pipetting a liquid into the one or more particles and filtering the liquid over the entire image acquisition range.

7. The particle analysis device according to claim 1, comprising a database, wherein
the database stores
information indicating the first criterion, the second criterion, and the third criterion, and
a program for making a determination related to the first criterion, the second criterion, and the third criterion.

8. The particle analysis device according to claim 7,
the particle analysis device being connected to an external computer via a communication network, and
the particle analysis device acquiring from the external computer:
information indicating the first criterion, the second criterion, or the third criterion; or
a program for making a determination related to the first criterion, the second criterion, or the third criterion.

9. The particle analysis device according to claim 1, wherein
in the second operation pattern, the image is acquired at an intermediate magnification lower than the first magnification and higher than the second magnification.

10. The particle analysis device according to claim 3, wherein
the display displays
a particle parameter input part for inputting a type and a state of the one or more particles, and
a result display part for displaying a result of the determination.

11. A particle analysis method for analyzing one or more particles, the particle analysis method being capable of operating in any of a plurality of operation patterns, wherein the plurality of operation patterns include
a first operation pattern for determining, after an image of one or more particles prepared in a first time is acquired at a first magnification, whether a form of a single particle meets a first criterion,
a second operation pattern for determining, after an image of a plurality of particles prepared in the first time is acquired, whether a brightness and an area of the plurality of particles meet a second criterion, and
a third operation pattern for determining, after an image of a plurality of particles prepared in a second time longer than the first time is acquired at a second magnification lower than the first magnification, whether a number of the plurality of particles meets a third criterion.
